(19) United States
(12) Patent Application Publication
(10) Pub. No.: US 2009/0093115 A1
(43) Pub. Date: Apr. 9, 2009

(54) METHOD FOR FORMING METAL LINE OF SEMICONDUCTOR DEVICE BY ANNEALING ALUMINUM AND COPPER LAYERS TOGETHER

(76) Inventor: Chang Soo PARK, Seoul (KR)

Correspondence Address: LADAS & PARRY LLP, 224 SOUTH MICHIGAN AVENUE, SUITE 1600, CHICAGO, IL, 60604, US

(21) Appl. No.: 12/043,186

(22) Filed: Mar. 6, 2008

(30) Foreign Application Priority Data
Oct. 5, 2007 (KR) 10-2007-0100220

(51) Int. Cl. H01L 21/768

(52) U.S. Cl. 438/653; 257/E21.584

(57) ABSTRACT

A metal line is formed to realize an improved electrical conductivity over the conventional aluminum metal lines. The metal line of a semiconductor device is made by forming an interlayer dielectric having a metal line forming region on a semiconductor substrate. A diffusion barrier on the interlayer dielectric is formed which includes a surface of the metal line forming region. A nucleus formation prevention layer is formed on upper ends of sidewalls of the metal line forming region and on a portion of the diffusion barrier which is placed on an upper surface of the interlayer dielectric. A laminated metal layer made of an aluminum layer and a copper layer is formed to fill the metal line forming region. A portion of the laminated metal layer, the nucleus formation prevention layer and the diffusion barrier is removed to expose the interlayer dielectric. The laminated metal layer is annealed into an annealed metal layer.

### CROSS-REFERENCE TO RELATED APPLICATIONS

The present application claims priority to Korean patent application number 10-2007-0100220 filed on Oct. 5, 2007, which is incorporated herein by reference in its entirety.

### BACKGROUND OF THE INVENTION

The present invention relates to a method for forming a metal line of a semiconductor device, and more particularly to a method for forming a metal line of a semiconductor device which can improve reliability of the semiconductor device and simplify a manufacturing process.

In general, in a semiconductor device, metal lines are formed to electrically connect elements or lines with each other, and contact plugs are formed to electrically connect upper and lower conductive layers with each other. As a material for the contact plugs and metal lines, aluminum having excellent electrical conductivity has been mainly used. Recently, in an effort to obtain electrical characteristics suitable for increasing the level of integration of a semiconductor device, the use of copper having more excellent electrical conductivity than aluminum has been highlighted in the art.

However, since copper has a narrow margin in photo and etching processes due to a high reflection level and a dry etching method for copper has not yet been developed, it is difficult to implement patterning of copper through reactive ion etching. Therefore, at the present time, the formation of copper metal lines is implemented using a damascene process.

In the damascene process, after holes for metal lines are defined in an interlayer dielectric, a Ta layer, a TaN layer or a Ta/TaN/Ta layer is deposited on the surfaces of the holes as a diffusion barrier for preventing diffusion of the interlayer dielectric and a metal layer. Then, after a metal layer for metal lines is formed on the diffusion barrier to a thickness for completely filling the holes for metal lines, by CMPing (chemically and mechanically polishing) the metal layer for metal lines and the diffusion barrier, metal lines are formed.

Meanwhile, in the case of forming aluminum metal lines using a damascene process, after depositing a first pure aluminum layer on a diffusion barrier through chemical vapor deposition, a second aluminum layer containing copper is deposited on the first pure aluminum layer through high temperature sputtering to completely fill holes for metal lines, thereby forming an aluminum alloy. Then, a CMPing process is implemented for the aluminum alloy containing copper and the diffusion barrier.

The deposition of an aluminum layer through a chemical vapor deposition can be divided into a blanket deposition method and a selective deposition method. These two methods have drawbacks as described below.

First, in the selective deposition method, only when the temperature of an aluminum source is decreased to no greater than 350° C., as a conductive layer is exposed on the bottom surfaces of contact holes, selectivity can be obtained. Therefore, in a conventional structure of a semiconductor device in which a diffusion barrier is deposited on the overall surface of a semiconductor substrate, the deposition of aluminum through the selective deposition method cannot be easily implemented. At this time, if the deposition temperature is increased to ensure easy deposition of aluminum, voids are likely to be formed on the bottom surfaces of metal line forming regions due to poor surface morphology, or it is difficult to recognize a pattern in a subsequent etching process so that a blanket etching process such as CMPing is additionally required.

Then, in the blanket deposition method, when doping copper into an aluminum layer in a structure having a high step and an extremely fine pattern, several problems can arise due to differences in step coverage among the upper surface, the sidewall and the bottom surface of the extremely fine pattern. For example, when assuming that a seed copper layer having a thickness of 2 nm is needed for doping 0.5 wt % copper, while depositing the aluminum layer for a predetermined time at a temperature of 230˜300° C., the aluminum layer, which is being deposited, and the seed copper layer, which is already deposited under the aluminum layer, continuously react with each other, and Al₂Cu is formed on the interface therebetween. As Al₂Cu formed in this way continuously grows, a hillock is produced, and due to the presence of the hillock, lower and upper metal lines are more likely to be short-circuited in a subsequent process.

Moreover, because the degree to which Al₂Cu grows depends on the amount and the time of the reaction between aluminum and copper, the size of Al₂Cu continuously increases as the process proceeds. Therefore, when subsequently conducting an etching process to form metal lines, since etching does not sufficiently occur due to the presence of copper contained in Al₂Cu, a bridge can be formed between adjoining metal lines. Hence, grown Al₂Cu serves as a factor that decreases a manufacturing yield.

As a result, the above-described problem deteriorates the reliability of metal lines, and a manufacturing cost increases due to addition of processes.

### SUMMARY OF THE INVENTION

An embodiment of the present invention is directed to a method for forming a metal line of a semiconductor device which can improve the reliability of the semiconductor device.

Further, an embodiment of the present invention is directed to a method for forming a metal line of a semiconductor device which can simplify a manufacturing process and reduce a manufacturing cost.

In one embodiment, a method for forming a metal line of a semiconductor device comprises the steps of forming an interlayer dielectric having a metal line forming region on a semiconductor substrate; forming a diffusion barrier on the interlayer dielectric including a surface of the metal line forming region; forming a nucleus formation prevention layer on upper ends of sidewalls of the metal line forming region and on a portion of the diffusion barrier which is placed on an upper surface of the interlayer dielectric; forming a metal layer made of an aluminum layer and a copper layer to fill the metal line forming region; removing the metal layer, the nucleus formation prevention layer and the diffusion barrier to expose the interlayer dielectric; and annealing the metal layer.

The metal line forming region is defined to have a structure including a trench or a structure including a trench and a via hole.

The diffusion barrier is formed of any one of a refractory metal, a refractory metal nitride layer, a refractory metal carbide layer, and an at least ternary metal compound.

The step of forming the nucleus formation prevention layer comprises the steps of depositing an Al layer or a Ti layer on upper ends of sidewalls of the metal line forming region and on a portion of the diffusion barrier which is placed on an upper surface of the interlayer dielectric; and exposing and thereby subsequently oxidizing the Al layer or the Ti layer in the atmosphere.

The step of depositing the Al layer or the Ti layer is implemented through sputtering.

The Al layer or the Ti layer is deposited to have a thickness of 20˜40 Å.

The step of forming the nucleus formation prevention layer comprises the steps of depositing an Al layer or a Ti layer on upper ends of sidewalls of the metal line forming region and on a portion of the diffusion barrier which is placed on an upper surface of the interlayer dielectric; and exposing the Al layer or the Ti layer in oxygen or oxygen containing inert gases under a vacuum condition.

The step of depositing the Al layer or the Ti layer is implemented through sputtering.

The Al layer or the Ti layer is deposited to have a thickness of 20˜40 Å.

The step of forming the nucleus formation prevention layer is implemented through plasma processing of a surface of the diffusion barrier in a condition in which a substrate bias is not applied.

The plasma processing is implemented in an atmosphere containing oxygen.

The step of forming the metal layer made of the aluminum layer and the copper layer comprises the steps of depositing the aluminum layer by flowing an aluminum-containing metal source gas and hydrogen; and depositing the copper layer on the aluminum layer by flowing a copper-containing metal source gas and hydrogen.

The step of depositing the aluminum layer and the step of depositing the copper layer are implemented at least one time.

The step of depositing the copper layer is implemented for a longer period than the step of depositing the aluminum layer.

The aluminum-containing metal source gas comprises DMAH (dimethylaluminumhydride), and the copper-containing metal source gas comprises copper(I) (hexafluoroacetylacetonate) (trimethylvinylsilane), {Cu[(hfac)(tmvs)]}.

The step of depositing the aluminum layer and the step of depositing the copper layer are implemented at a temperature of 250˜350° C. for 30˜120 seconds.

Annealing of the metal layer is implemented at a temperature of 500˜600° C. for 60˜300 seconds.

After the step of annealing the metal layer, the method further comprises the step of forming a capping layer on a surface of the metal layer.

The capping layer is formed as an AlN layer.

The AlN layer is formed by exposing a surface of the aluminum layer containing copper in N₂H₂ gas or by processing the aluminum layer containing copper in plasma using NH₃ or nitrogen containing gases.

### BRIEF DESCRIPTION OF THE DRAWINGS

FIGS. 1A through 1F are cross-sectional views illustrating the processes of a method for forming a metal line of a semiconductor device in accordance with an embodiment of the present invention.

### DESCRIPTION OF SPECIFIC EMBODIMENTS

In an embodiment of the present invention, a diffusion barrier is formed on the surface of a metal line forming region, and a nucleus formation prevention layer is formed on the upper ends of the sidewalls of the metal line forming region and on the upper surface of the diffusion barrier. Afterwards an aluminum layer and a copper layer are alternately formed on the sidewalls and the bottom wall of the metal line forming region excluding the upper ends of the sidewalls of the metal line forming region on which the nucleus formation prevention layer is formed, by annealing the aluminum layer and the copper layer, through diffusion of copper into aluminum, a metal layer for metal lines, which is made of the aluminum layer containing copper, is formed. After forming the metal layer in the metal line forming region, by substituting, through annealing, the portion of the metal layer which is exposed over the metal line forming region, a capping layer is formed.

By these facts, due to the presence of the nucleus formation prevention layer, the metal layer made of the aluminum layer and the copper layer can be selectively formed from the sidewalls and the bottom surface of the metal line forming region. According to this, it is possible to prevent a copper layer from being formed on the surface having a large exposed area, such as on the upper end of the metal line forming region. Thus, in the present invention, since it is possible to prevent Al₂Cu from being formed through reaction between aluminum and copper, it is possible to prevent a bridge from being formed between adjoining metal lines due to the presence of Al₂Cu and a defect from being caused in a semiconductor device.

Further, in the present invention, after forming the aluminum layer and the copper layer in the metal line forming region, by implementing annealing and thereby diffusing copper into the aluminum layer, the aluminum layer containing copper is formed in the metal line forming region. At this time, because the moving distance of aluminum grain is restrained in the metal line forming region having a limited area, crystal grain grows to a large size. Therefore, in the present invention, since crystals can be grown in the metal line forming region to have a size similar to that of a single crystal, the reliability of a semiconductor device can be improved.

In addition, in the present invention, due to the fact that the capping layer is formed on the exposed upper surface of the metal layer through implementing annealing after formation of the metal layer, it is possible to prevent a hillock from being formed, which is otherwise formed on the exposed upper surface of the conventional damascened metal line.

Hereafter, a specific embodiment of the present invention will be described in detail with reference to the attached drawings.

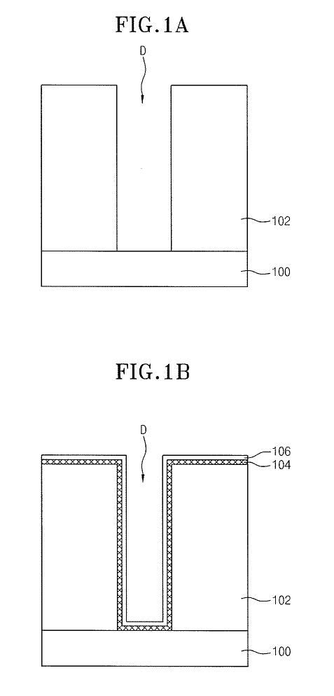

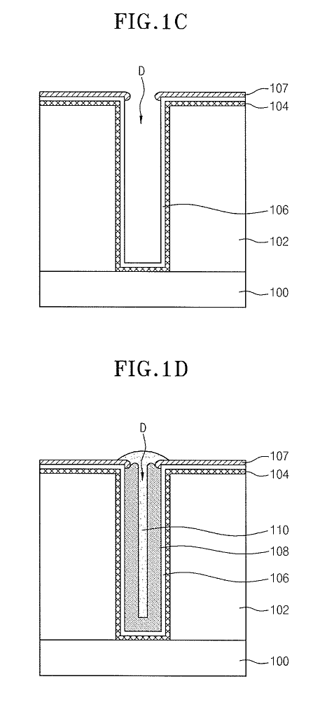

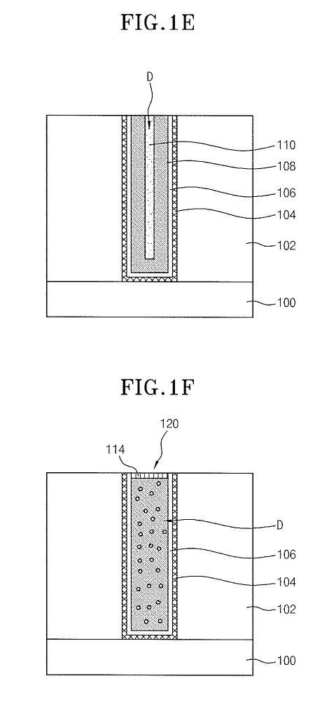

FIGS. 1A through 1F are cross-sectional views illustrating the processes of a method for forming a metal line of a semiconductor device in accordance with an embodiment of the present invention.

Referring to FIG. 1A, an interlayer dielectric 102 is formed on a semiconductor substrate 100 which is formed with a lower structure (not shown) which may include components such as, gates and capacitors (also not shown). In order to define a metal line forming region in which a metal line is to be subsequently formed, a photoresist pattern (not shown) is formed on the interlayer dielectric 102. By etching the interlayer dielectric 102 using the photoresist pattern as an etch mask, a metal line forming region D is defined in the interlayer dielectric 102. The metal line forming region D is defined through a single damascene process or a dual damascene process. When the single damascene process is employed, the metal line forming region D is defined to have a structure including a single trench, and when the dual damascene process is used, the metal line forming region D is defined to have a structure including a via hole and a trench.

Referring to FIG. 1B, an adhesive layer 104 made of a suitable layer such as a Ti layer is formed on the interlayer dielectric 102 including the surface of the metal line forming region D. A diffusion barrier 106 made of any one of a refractory metal nitride layer, a refractory metal carbide layer, and an at least ternary metal compound is formed on the surface of the adhesive layer 104.

Referring to FIG. 1C, a metal layer such as an Al layer or a Ti layer is deposited on the upper ends of the sidewalls of the metal line forming region D and on the portion of the diffusion barrier 106 which is placed on the upper surface of the interlayer dielectric 102. Then, by exposing and thereby oxidizing the Al layer or the Ti layer in the atmosphere or by exposing the Al layer or the Ti layer in oxygen or oxygen containing inert gases under a vacuum condition, a nucleus formation prevention layer 107 is only formed on the upper ends of the sidewalls of the metal line forming region D and on the upper surface of the diffusion barrier 106. The deposition of the metal layer such as the Al layer or the Ti layer is implemented through sputtering, preferably, to a thickness of 20˜40 Å.

In addition to forming the nucleus formation prevention layer 107 through the deposition of the metal layer such as the Al layer or the Ti layer, the nucleus formation prevention layer 107 can be formed through plasma processing of the surface of the diffusion barrier 106 in a condition in which a substrate bias is not applied. At this time, the plasma processing is implemented under an atmosphere containing oxygen.

Referring to FIG. 1D, an aluminum layer 108 is deposited in the metal line forming region D by alternately flowing an aluminum-containing metal source gas made of a suitable material such as DMAH (dimethylaluminumhydride) and hydrogen. A copper layer 110 is deposited on the aluminum layer 108 by alternately flowing a copper-containing metal source gas made of a suitable material such as Cu[(hfac)(tmvs)] and hydrogen. The deposition of the aluminum layer 108 and the copper layer 110 is implemented at a temperature of 250˜350° C. under a low pressure, preferably, in an atmosphere having substantially no oxygen or subjected to a vacuum condition for 30˜120 seconds. The aluminum layer 108 and the copper layer 110 can be deposited at least one time depending upon the concentration of copper that is required for the formation of the aluminum alloy. By extending the deposition time of the copper layer 110, the concentration of the copper can be adjusted.

Referring to FIG. 1E, in order to remove the portions of the copper layer 110 and the aluminum layer 108 which are deposited over the metal line forming region D, the copper layer 110, the aluminum layer 108, the nucleus formation prevention layer 107, the diffusion barrier 106 and the adhesive layer 104 are removed by CMP.

Referring to FIG. 1F, by annealing the metal layer including the aluminum layer 108 and the copper layer 110 at a temperature of 500˜600° C. for 60˜300 seconds, a metal line 120 made of the aluminum layer containing copper is formed in the metal line forming region D through diffusion of copper into the aluminum layer 108.

A capping layer 114 made of an AlN layer is formed on the surface of the metal line 120 which is made of the aluminum layer containing copper. The capping layer 114 made of the AlN layer is formed by exposing the surface of the aluminum layer containing copper in N₂H₂ gas or by processing the aluminum layer containing copper in plasma using NH₃ or nitrogen containing gases.

As is apparent from the above description, in the present invention, due to the fact that a metal layer made of an aluminum layer and a copper layer is selectively formed from the sidewalls and the bottom surface of a metal line forming region, it is possible to minimize the occurrence or to prevent entirely Al₂Cu from being formed on the surface of the metal line forming region through reaction between aluminum and copper. According to this, it is possible to minimize the occurrence or to prevent entirely a bridge from being formed between adjoining metal lines and a defect from being caused in a semiconductor device.

Further, in the present invention, after forming the aluminum layer and the copper layer in the metal line forming region, by implementing annealing and thereby diffusing copper into the aluminum layer, the aluminum layer containing copper is formed in the metal line forming region. At this time, because the moving distance of aluminum grain is restrained in the metal line forming region having a limited area, crystal grain grows to a large size. Therefore, in the present invention, differently from on a plane, since the aluminum layer, which contains copper and has a crystal size similar to that of a single crystal, can be formed, the reliability of a semiconductor device can be improved.

In addition, in the present invention, due to the fact that a capping layer is formed on the metal layer, it is possible to minimize the occurrence or to prevent entirely hillocks from being formed on the exposed upper surface of a metal line.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A method for forming a metal line of a semiconductor device, comprising the steps of:
forming an interlayer dielectric having a metal line forming region on a semiconductor substrate;
forming a diffusion barrier on the interlayer dielectric including a surface of the metal line forming region;
forming a nucleus formation prevention layer on upper ends of sidewalls of the metal line forming region and on a portion of the diffusion barrier which is placed on an upper surface of the interlayer dielectric;
forming a laminated metal layer comprising an aluminum layer and a copper layer to fill the metal line forming region;
removing a portion of the laminated metal layer, the nucleus formation prevention layer and the diffusion barrier to expose the interlayer dielectric; and
annealing the laminated metal layer into an annealed metal layer.

2. The method according to claim 1 further comprising forming an adhesive layer directly on to the interlayer dielectric including onto the surface of the metal line forming region.

3. The method according to claim 2 wherein the adhesive layer is made of titanium.

4. The method according to claim 1, wherein the metal line forming region is defined to have a structure including a trench or a structure including a trench and a via hole.

5. The method according to claim 1, wherein the diffusion barrier is formed of any one of a refractory metal, a refractory metal nitride layer, a refractory metal carbide layer, and an at least ternary metal compound.

6. The method according to claim 1, wherein the step of forming the nucleus formation prevention layer comprises the steps of:
depositing an Al layer or a Ti layer on upper ends of sidewalls of the metal line forming region and on a portion of the diffusion barrier which is placed on an upper surface of the interlayer dielectric; and
exposing and thereby oxidizing the Al layer or the Ti layer in the atmosphere.

7. The method according to claim 6, wherein the step of depositing the Al layer or the Ti layer is implemented through sputtering.

8. The method according to claim 6, wherein the Al layer or the Ti layer is deposited to have a thickness of 20˜40 Å.

9. The method according to claim 1, wherein the step of forming the nucleus formation prevention layer comprises the steps of:
depositing an Al layer or a Ti layer on upper ends of sidewalls of the metal line forming region and on a portion of the diffusion barrier which is placed on an upper surface of the interlayer dielectric; and
exposing the Al layer or the Ti layer to oxygen under a vacuum condition.

10. The method according to claim 9, wherein the step of depositing the Al layer or the Ti layer is implemented through sputtering.

11. The method according to claim 9, wherein the Al layer or the Ti layer is deposited to have a thickness of 20˜40 Å.

12. The method according to claim 1, wherein the step of forming the nucleus formation prevention layer is implemented through plasma processing of a surface of the diffusion barrier in a condition in which a substrate bias is not applied.

13. The method according to claim 10, wherein the plasma processing is implemented in an atmosphere containing oxygen.

14. The method according to claim 1, wherein the step of forming the laminated metal layer made of the aluminum layer and the copper layer comprises the steps of:
depositing the aluminum layer by flowing an aluminum-containing metal source gas and hydrogen; and
depositing the copper layer on the aluminum layer by flowing a copper-containing metal source gas and hydrogen.

15. The method according to claim 14, wherein the step of depositing the aluminum layer and the step of depositing the copper layer are implemented at least one time.

16. The method according to claim 14, wherein the step of depositing the copper layer is implemented for a longer time period than the step of depositing the aluminum layer.

17. The method according to claim 14, wherein the aluminum-containing metal source gas comprises DMAH (dimethylaluminumhydride), and the copper-containing metal source gas comprises Cu[(hfac)(tmvs)] (copper(I) (hexafluoroacetylacetonate) (trimethylvinylsilane)).

18. The method according to claim 12, wherein the step of depositing the aluminum layer and the step of depositing the copper layer are implemented at a temperature of 250˜350° C. for 30˜120 seconds.

19. The method according to claim 1, wherein annealing of the metal layer is implemented at a temperature of 500˜600° C. for 60˜300 seconds.

20. The method according to claim 1, wherein, after the step of annealing the laminated metal layer into the annealed metal layer, the method further comprises the step of:
forming a capping layer on a surface of the annealed metal layer.

21. The method according to claim 20, wherein the capping layer comprises an AlN layer.

22. The method according to claim 21, wherein the AlN layer is formed by exposing a surface of the aluminum layer containing copper of the annealed metal layer with N₂H₂ gas or by processing the aluminum layer containing copper of the annealed metal layer in plasma with NH₃ or nitrogen containing gases.
